(19) United States
(12) Patent Application Publication
(10) Pub. No.: US 2019/0171931 A1
(43) Pub. Date: Jun. 6, 2019

(54) SYSTEMS AND METHODS FOR MACHINE LEARNING PROCESSOR WITH INTRA-DIE AND INTER-DIE WIRELESS COMMUNICATION

(71) Applicant: Vathys, Inc., Portland, OR (US)

(72) Inventor: Tapabrata GHOSH, Portland, OR (US)

(21) Appl. No.: 16/206,741

(22) Filed: Nov. 30, 2018

Related U.S. Application Data
(60) Provisional application No. 62/594,532, filed on Dec. 4, 2017.

(51) Int. Cl. G06N 3/063; G06N 20/00; H04B 5/00; H01L 25/065

(52) U.S. Cl. CPC G06N 3/063; G06N 20/00; H04B 5/0031; H04B 5/0093; G06F 17/13; H01L 25/0657; H01L 2225/06531; H01L 2225/06541; H04B 5/0012

(57) ABSTRACT

The need for specialized machine learning processors has become a major focal point in the industry as the computation demanded by machine learning workloads grows rapidly. However, the industry has quickly come to a roadblock as the industry realizes, in the context of machine learning, the device memory is more important than complex computation ability. As a result, there has been renewed interest in three dimensional and “2.5D” machine learning processors, which are more suited to handle large volume of data. However, conventional multi-layer devices use through silicon vias (TSVs) which have a number of disadvantages and drawbacks. To address these issues, method and devices are disclosed that allow wireless communication between processing layers in a 3D and/or 2.5D integrated dice machine learning processors.

### CROSS-REFERENCE TO RELATED APPLICATIONS

This application claims the benefit of priority of U.S. Provisional Application No. 62/594,532 filed on Dec. 4, 2017 entitled “A Novel Machine Learning Processor Employing Intra-Die and Inter-Die Wireless Communications,” content of which is incorporated herein by reference in its entirety and should be considered a part of this specification.

### BACKGROUND

### Field of the Invention

The present invention relates to the field of processors designed for carrying out machine learning operations (e.g., processing neural networks operations and algorithms). In particular, systems and methods of communication between dice in a machine learning processor (e.g., dice stacked in a substantially vertical manner, termed “3D”) is disclosed.

### Description of the Related Art

Three-dimensional integration of silicon wafer and/or dice has long been a goal for manufacturing machine learning processors to achieve higher level of efficiency demanded by such processors. Three-dimensional integration in the context of IC manufacturing and/or packaging is a broad term that can apply to technologies such as 3D wafer-level packaging (3DWLP), 2.5D and 3D interposer-based integration, 3D stacked ICs (3D-SiCs), monolithic 3D ICs, 3D heterogeneous integration, and 3D systems integration. An example of a conventional three-dimensional technology in literature includes, the Stanford University TETRIS project which uses TSVs for 3D integration. An industry example of conventional technology includes the Volta V100 which uses TSVs for 2.5D integration.

Efforts to achieve three-dimensional integration so far have included using micro-bumps and/or through-silicon vias (TSVs). Such methods have a number of inefficiencies and drawbacks, preventing the widespread adoption of 2.5D or 3D stacking/integration for machine learning processors. For example, conventional three-dimensional integration techniques are costly, and suffer from poor yield. Heat build-up, design complexity and large chip-foot print are among other inefficiencies of the current 3D integration technology. Accordingly, there is a need for improved three-dimensional integration technology to address the above shortcomings.

### SUMMARY

In one aspect of the invention, a machine learning processor optimized for carrying out machine learning operations is disclosed. The machine learning processor includes: a substrate; a plurality of processing dice on the substrate, wherein one or more of the plurality of the processing dice are substantially vertically stacked on one another and on the substrate and the processing dice comprise circuitry to carry out machine learning operations and one or more machine learning operations is carried out with circuitry on or embedded in two or more of the plurality of processing dice; and one or more wireless communication components embedded in and/or on one or more of the substrate and the plurality of processing dice, wherein the wireless communication components carry wireless communication signals between one or more of the substrate and the plurality of processing dice and the circuitry therein and wherein the operations of the machine learning processor comprises the communication signals.

In one embodiment, the one or more wireless communication components comprise components providing electromagnetic coupling between the components.

In another embodiment, the electromagnetic coupling comprises one or more of capacitive coupling and inductive coupling.

In one embodiment, the electromagnetic coupling includes capacitive coupling and metal layers in the plurality of dice and/or substrate form the capacitive coupling between the plurality of dice and/or the substrate.

In some embodiments, the electromagnetic coupling includes capacitive coupling, and wherein a transistor gate in a processing die is used to form a parallel plate of a capacitive coupling.

In some embodiments, the electromagnetic coupling includes inductive coupling and metal layers in a processing die are arranged in substantially polygonic shape to form an inductor coil.

In one embodiment, the wireless communication components carry wireless communication signals between one or more regions of one or more of the substrate and the plurality of dice.

In one embodiment, the one or more wireless communication components include components providing communication via electromagnetic radiation.

In another embodiment, the wireless communication components include an antenna and/or an antenna array.

In one embodiment, the wireless communication components include components providing wireless communication via one or more of capacitive coupling, inductive coupling and electromagnetic radiation.

In some embodiments, the communication signals are generated via a communication protocol.

In another embodiment, the communication protocol includes differential signaling.

In some embodiments, differential signaling includes one or more of Chordal coding, PAM-X, CNRZ-5, CNRZ-X, permutation vectors, vector coding, and line coding.

In another aspect of the invention, a method of manufacturing a machine learning processor is disclosed. The method includes: vertically stacking a plurality of processing dice, wherein each die comprises circuitry configured to carry out machine learning processes; and forming a wireless communication link between processing dice, wherein the circuitry in two or more processing dice are configured to carry out machine learning processes via the wireless communication link.

In some embodiments, the wireless communication link includes one or more of capacitive coupling, inductive coupling and electromagnetic radiation.

In some embodiments, forming the wireless communication link includes: forming metal layers in the plurality of processing dice to generate parallel plate capacitors between the plurality of processing dice.

In one embodiment, forming the wireless communication link includes: using transistor gates in the plurality of processing dice to form parallel plate capacitors between the plurality of processing dice.

In another embodiment, forming the wireless communication link comprises arranging metal layers in the plurality of processing dice in substantially polygonic shape to form inductor coils.

In another aspect of the invention, a machine learning processor is disclosed. The machine learning processor includes: a plurality of vertically stacked processing dice comprising circuitry to carry out machine learning operations; wireless communication means embedded in two or more of the plurality of processing dice and configured to carry wireless communication signals between one or more of the plurality of processing dice and the circuitry therein and wherein the machine learning operations comprise the communication signals.

In one embodiment, the wireless communication means comprises one or more of electromagnetic coupling means and electromagnetic radiation means.

### BRIEF DESCRIPTION OF THE DRAWINGS

These drawings and the associated description herein are provided to illustrate specific embodiments of the invention and are not intended to be limiting.

FIG. 1a illustrates a diagram of a prior art 2D machine learning processor.

FIG. 1b illustrates a diagram of a prior art 2.5D or 3D machine learning processor.

FIG. 2a illustrates a diagram of a prior art 3D stacked/integrated processor using TSVs for dice communication.

FIG. 2b illustrates a diagram of a prior art 2.5D stacked/integrated processor using TSVs for dice communication.

FIG. 3a illustrates a diagram of an embodiment, where the electromagnetic coupling method of capacitive coupling is used to provide dice communication within/between layers of a 3D stacked/integrated machine learning processor.

FIG. 3b illustrates a diagram of another embodiment, where the electromagnetic coupling method of capacitive coupling is used to provide dice communication within/between layers of a 3D stacked/integrated machine learning processor.

FIG. 3c illustrates a diagram of an embodiment, where the electromagnetic coupling method of capacitive coupling is used to provide dice communication within/between layers of a 2.5D stacked/integrated machine learning processor.

FIG. 4a illustrates a diagram of an embodiment, where the electromagnetic coupling method of inductive coupling is used to provide dice communication within/between layers of a 3D stacked/integrated machine learning processor.

FIG. 4b illustrates a diagram of an embodiment, where the electromagnetic coupling method of inductive coupling is used to provide dice communication within/between layers of a 2.5D stacked/integrated machine learning processor.

FIG. 5 illustrates a diagram of an embodiment, where the wireless communication method of electromagnetic radiation is used to provide dice communication within/between a 2.5D stacked/integrated machine learning processor.

### DETAILED DESCRIPTION

The following detailed description of certain embodiments presents various descriptions of specific embodiments of the invention. However, the invention can be embodied in a multitude of different ways as defined and covered by the claims. In this description, reference is made to the drawings where like reference numerals may indicate identical or functionally similar elements.

Unless defined otherwise, all terms used herein have the same meaning as are commonly understood by one of skill in the art to which this invention belongs. All patents, patent applications and publications referred to throughout the disclosure herein are incorporated by reference in their entirety. In the event that there is a plurality of definitions for a term herein, those in this section prevail.

When the terms “one”, “a” or “an” are used in the disclosure, they mean “at least one” or “one or more”, unless otherwise indicated.

Before any embodiments are explained in detail, it is understood that the disclosed technology is not limited in its application to the details of construction and the arrangement of components set forth in the following description or illustrated in the following drawings. The disclosed technology is capable of other embodiments and of being practiced or of being carried out in various ways. Furthermore, it is understood that sometimes a different number of apparati, systems and methods may be illustrated and/or described but the disclosed technology may be embodied as containing any number of such aspects. Finally, it should be understood that some embodiments may combine presented aspects. For example, a specific embodiment may utilize both inductive coupling and capacitive coupling.

Machine learning processors can be fabricated by vertically stacking die (e.g., round or square silicon die) layers building three-dimensional processors to carry out the operations of the processor. Each layer can include various logic circuits, transistors, capacitors, resistors, inductors or other electrical components. The various layers within a 3D machine learning processor need to be connected or communicate electrically or wirelessly to provide processor functionality. Sometimes a signal on one layer is communicated to another layer. TSV or other physical, electrical connection between vertically stacked layers achieve the communication objective, but introduce technical difficulties of their own.

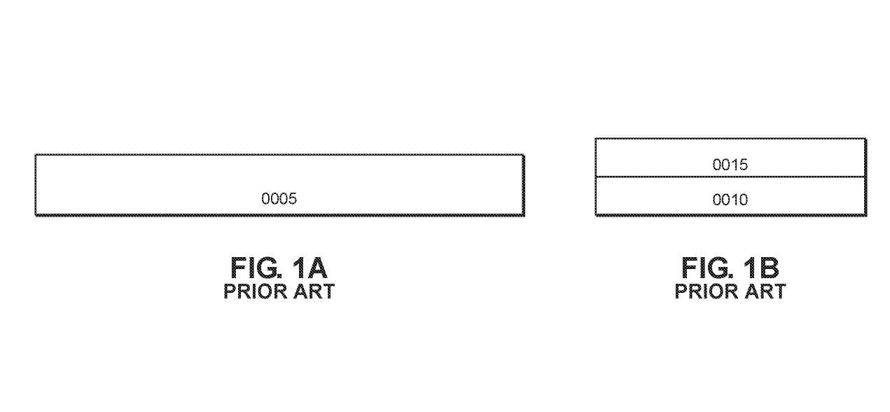

FIG. 1a is a diagram of a prior art 2D machine learning processor built on a single die 0005. No other die is substantially parallel to the die 0005. FIG. 1b is a diagram of a prior art 2.5D or 3D machine learning processor built on two dice 0010 and 0015, which are fabricated substantially vertical with respect to each other.

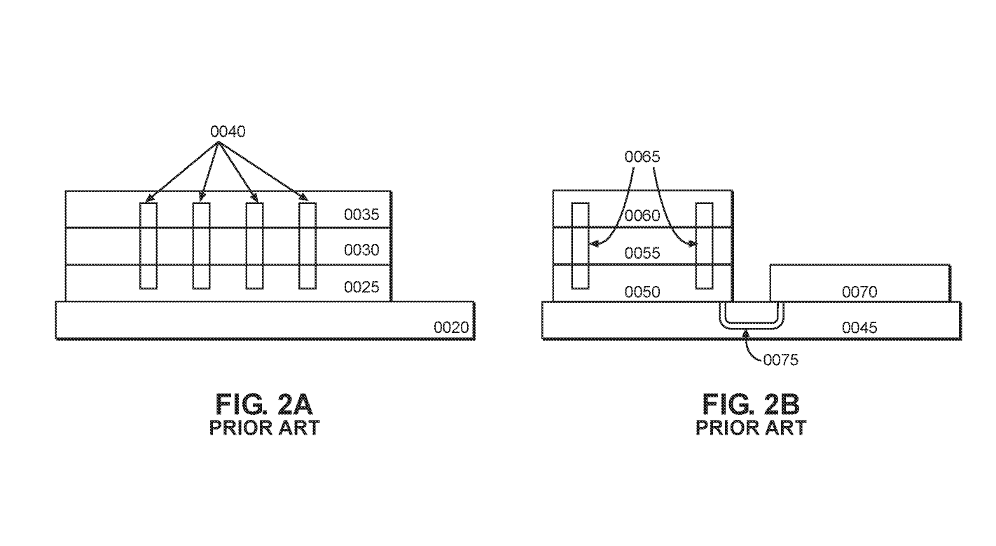

FIG. 2a illustrates an example diagram of a prior art 3D stacked/integrated machine learning processor. Dice 0025, 0030 and 0035 are stacked vertically to create a 3D stacked/integrated machine learning processor. An optional substrate 0020 may be used. TSVs 0040 provide vertical interconnects between dice 0025, 0030, and 0035 to allow electrical connection between them. TSVs 0040 are present in many conventional 3D machine learning processors and suffer from a number of limitations, including large area impact, large keep out zones (KOZs), high power consumption, poor bandwidth requirement of electrostatic discharge protection and extremely high parasitic capacitance.

FIG. 2b illustrates a diagram of a prior art 2.5D integrated/stacked machine learning processor fabricated using TSVs 0065. Dice 0050, 0055 and 0060 are stacked vertically with TSVs 0065 providing electrical connection between them. An optional substrate 0045 can be used and the dice 0050, 0055, and 0060 are connected via substrate interconnect 0075 to another die 0070. Similar to the machine learning processor of FIG. 2a, the machine learning processor of FIG. 2b suffers from a number of limitations, including large area impact, large keep out zones (KOZs), high power consumption, poor bandwidth requirement of electrostatic discharge protection and extremely high parasitic capacitance.

Wireless communication within and/or between layers of a vertically stacked machine learning processor can address several issues present in conventional technologies. Such wireless communication can be implemented via electromagnetic coupling mechanisms, capacitive links, inductive links, electromagnetic radiation and/or other on-chip wireless technology.

Examples of communication within and/or between layers and circuits therein can include, generating a signal, encoding and/or decoding a signal using Os and is, communication using a communication protocol, such as differential signaling (e.g., Chordal coding, PAM-X, CNRZ-5, CNRZ-X, permutation vectors, vector coding, line coding and any combination of the aforementioned), and/or other on-chip communication technology.

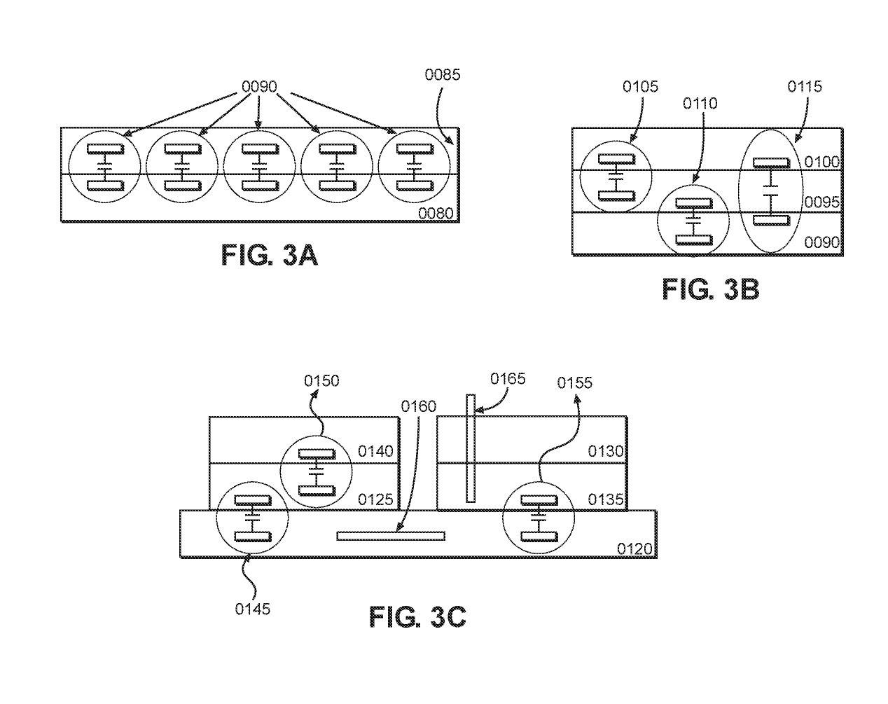

FIG. 3a illustrates an embodiment, where the electromagnetic coupling mechanism of capacitive coupling is employed to facilitate wireless communication between 3D stacked/integrated dice to build a 3D machine learning processor. Dice 0080 and 0085 are two dice that are fabricated substantially vertically positioned such that they may be at least partially considered to be in a “3D” configuration. The dice 0080 and 0085 may communicate through any number of capacitive links 0090. While only two dice 0080 and 0085 are illustrated here for the purposes of brevity of illustration, the embodiment can be implemented in any number of dies. Additionally, capacitive coupling providing communication between dies need not be limited to only adjacent dice. For example, FIG. 3b illustrates a machine learning processor according to an embodiment, where dice 0090, 0095 and 0100 are stacked vertically and capacitive links 0105, 0110 and 0115 are used for providing communication between three dice 0090, 0095 and 0100. Capacitive link 0105 provides communication between dice 0096 and 0100. Capacitive link 0110 provides communication between dice 0090 and 0095. Capacitive link 0115 provides communication between dice 0090 and 0100.

Example capacitive coupling links 0090, 0105, 0115 and other similar capacitive links can be created by fabricating metal layer regions in stacked dice, such that alignment of metal layers in dice forms one or more capacitors between the metal layers. Charging and discharging such capacitive coupling links can be used to implement communication between stacked dice. In one embodiment, the gate of transistors from different stacked dice layers can be used and aligned such that a capacitor forms between the transistor gates and charging/discharging that capacitor can be used to provide communication between stacked dice where the transistor gates are formed. Various semiconductor fabrication processes, for example, deposition, etching, patterning using lithography, doping and/or other suitable fabrication techniques may be employed to fabricate the capacitive coupling links described above.

FIG. 3c illustrates a 2.5D stacked/integrated machine learning processor utilizing wireless communication according to an embodiment. The machine learning processor of FIG. 3c optionally includes substrate/interposer 0120 and stacked dice 0130 and 0135. The substrate/interposer 0120 can provide horizontal connections 0160 between vertically stacked dice 0130, 0135 and another set of vertically stacked dice 0125 and 0140, as shown. Vertically stacked Dice 0130, 0135 may utilize a capacitive link 0155 to communicate to the substrate/interposer 0120. Disclosed capacitive links are compatible with conventional TSV connections and a combination of TSV and wireless linking (e.g., capacitive linking) may be used to achieve various Integrated Circuit (IC) and/or packaging design objectives. For example, vertically staked dice 0130 and 0135 can optionally use a TSV connection 0165 for purposes such as mechanical stability and/or power delivery. Vertically stacked dice 0125, 0140 can utilize a capacitive link 0145 to communicate with the substrate/interposer 0120. In the example shown, another capacitive link 0150 can provide communication between dies 0125 and 0140. The number and arrangement of capacitive links can depend on a variety of factors including the electrical functionality implemented by the vertically stacked dice, chip size, design and/or manufacturing considerations, and other factors.

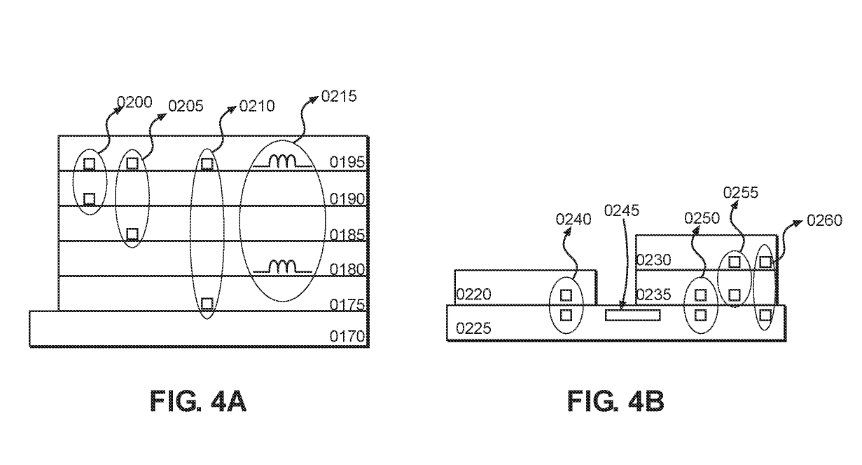

FIG. 4a illustrates an embodiment, where the electromagnetic coupling mechanism of inductive coupling is employed to facilitate wireless communication between 3D stacked/integrated dice to make a 3D machine learning processor. The 3D machine learning processor of FIG. 4a can optionally include a substrate/interposer 0170 upon which a 3D stacked dice architecture may be fabricated. Dice 0175, 0180, 0185, 0190 and 0195 can be fabricated substantially vertically and considered to be at least partially in a “3D” configuration. The dice 0175, 0180, 0185, 0190 and 0195 may wirelessly communicate using any number of inductive links 0200, 0205, 0210 and 0215. The inductive links 0200, 0205, 0210 and 0215 may be fabricated in their respective semiconductor dies in any number of ways depending on the fabrication process or design considerations employed.

As described, the processor communications can be carried out via wireless links described herein as well as conventional communication techniques (e.g., TSV) and/or any combination thereof as determined by the design objectives/constrains of a machine learning processor.

In one embodiment, the inductive links 0200, 0205, 0210 and 0215 can be formed by depositing or implanting a plurality of inductor coils. In one embodiment, the metal layers of a semiconductor chip may be used for the creation of inductor coils. In some embodiments, metal layers in dice can be arranged in polygonic shape (e.g., square, rectangle, circle, oval, etc.) to form inductive coils. In another embodiment, a ferromagnetic core may be placed in the center and/or above the inductor coil regions to enhance the inductance. In one embodiment, topological insulator-based quantum inductors may be used. Various semiconductor fabrication processes, for example, deposition, etching, patterning using lithography, doping and/or other suitable fabrication techniques may be employed to fabricate the inductive coupling links described above.

FIG. 4b illustrates a 2.5D stacked/integrated machine learning processor utilizing inter/intra die wireless communication according to an embodiment. The processor of FIG. 4b includes an optional substrate/interposer 0225. Die 0220 can be formed to use inductive coupling link 0240 to wirelessly communicate with interconnects and/or circuits within and/or through the substrate/interposer 0225. The substrate/interposer 0225 can provide horizontal connections 0245 between die 0220 and vertically stacked dies 0230, 0235. One or more inductive links can be used to provide wireless communication between various layers. For example, inductive link 0250 can provide wireless communication between die 0235 and substrate/interposer 0225. Inductive link 0255 can provide wireless communication between dice 0230 and 0235. Inductive link 0260 can provide wireless communication between die 0230 and the substrate/interposer 0225.

As described, the illustrated wireless communication links and/or their locations are provided as examples. It is understood that the number, location and/or type of inter/intra die wireless communication links vary depending on the design objectives/constraints of a multilayer machine learning processors and/or circuits and signals implemented in its respective layers.

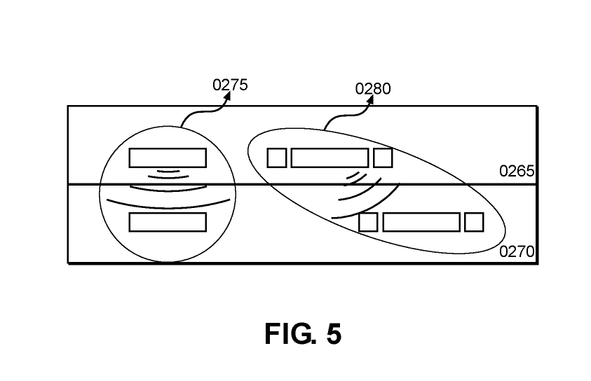

FIG. 5 illustrates a diagram of a machine learning processor built using vertically stacked die layers, where electromagnetic radiation is employed according to an embodiment to facilitate wireless communication between dies. In one embodiment, one or more antenna or antenna arrays 0275 and 0280 are used to generate and receive messages, signals and/or communication using electromagnetic radiation.

As described earlier, the disclosed wireless communication links address several shortcoming and issues present in conventional communication techniques such as TSVs. For example, the disclosed wireless communication links have a smaller foot print on a die and can be less complex and costly to fabricate and therefore can improve yield when fabricating machine learning processors.

The term “processor” can refer to various microprocessors, controllers, and/or hardware and software optimized for loading and executing software programming instructions or processors including processing units optimized for handling high volume matrix data related to machine learning algorithms. Examples of processors built according to the described techniques can be used in a variety of applications, including applications in the field of artificial intelligence (AI) and related fields. For example, a machine learning processor built according to the described embodiments can be configured to perform inference and/or training of a neural network. Other applications of the disclosed technology exist and can readily be ascertained by persons of ordinary skill in the art.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first, second, other and another and the like may be used solely to distinguish one entity or action from another without necessarily requiring or implying any actual such relationship or order between such entities or actions.

The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various implementations. This is for purposes of streamlining the disclosure and is not to be interpreted as reflecting an intention that the claimed implementations require more features than are expressly recited in each claim. Rather, as the following claims reflect, inventive subject matter lies in less than all features of a single disclosed implementation. Thus, the following claims are hereby incorporated into the Detailed Description, with each claim standing on its own as a separately claimed subject matter.

What is claimed is:

1. A machine learning processor optimized for carrying out machine learning operations, the processor comprising:
a substrate;
a plurality of processing dice on the substrate, wherein one or more of the plurality of the processing dice are substantially vertically stacked on one another and on the substrate and the processing dice comprise circuitry to carry out machine learning operations and one or more machine learning operations is carried out with circuitry on or embedded in two or more of the plurality of processing dice; and
one or more wireless communication components embedded in and/or on one or more of the substrate and the plurality of processing dice, wherein the wireless communication components carry wireless communication signals between one or more of the substrate and the plurality of processing dice and the circuitry therein and wherein the operations of the machine learning processor comprises the communication signals.

2. The processor of claim 1, wherein the one or more wireless communication components comprise components providing electromagnetic coupling between the components.

3. The processor of claim 2, wherein the electromagnetic coupling comprises one or more of capacitive coupling and inductive coupling.

4. The processor of claim 3, wherein the electromagnetic coupling comprises capacitive coupling and metal layers in the plurality of dice and/or substrate form the capacitive coupling between the plurality of dice and/or the substrate.

5. The processor of claim 3, wherein the electromagnetic coupling comprises capacitive coupling, and wherein a transistor gate in a processing die is used to form a parallel plate of a capacitive coupling.

6. The processor of claim 3, wherein the electromagnetic coupling comprises inductive coupling and metal layers in a processing die are arranged in substantially polygonic shape to form an inductor coil.

7. The processor of claim 1, wherein the wireless communication components carry wireless communication signals between one or more regions of one or more of the substrate and the plurality of dice.

8. The processor of claim 1, wherein the one or more wireless communication components comprise components providing communication via electromagnetic radiation.

9. The processor of claim 8, wherein the wireless communication components comprise an antenna and/or an antenna array.

10. The processor of claim 1, wherein the wireless communication components comprise components providing wireless communication via one or more of capacitive coupling, inductive coupling and electromagnetic radiation.

11. The processor of claim 1, wherein the communication signals are generated via a communication protocol.

12. The processor of claim 11, wherein the communication protocol comprises differential signaling.

13. The processor of claim 12, wherein differential signaling comprises one or more of Chordal coding, PAM-X, CNRZ-5, CNRZ-X, permutation vectors, vector coding, and line coding.

14. A method of manufacturing a machine learning processor, comprising:
vertically stacking a plurality of processing dice, wherein each die comprises circuitry configured to carry out machine learning processes; and
forming a wireless communication link between processing dice, wherein the circuitry in two or more processing dice are configured to carry out machine learning processes via the wireless communication link.

15. The method of claim 14, wherein the wireless communication link comprises one or more of capacitive coupling, inductive coupling and electromagnetic radiation.

16. The method of claim 14, wherein forming the wireless communication link comprises: forming metal layers in the plurality of processing dice to generate parallel plate capacitors between the plurality of processing dice.

17. The method of claim 14, wherein forming the wireless communication link comprises: using transistor gates in the plurality of processing dice to form parallel plate capacitors between the plurality of processing dice.

18. The method of claim 14, wherein forming the wireless communication link comprises arranging metal layers in the plurality of processing dice in substantially polygonic shape to form inductor coils.

19. A machine learning processor comprising:
a plurality of vertically stacked processing dice comprising circuitry to carry out machine learning operations;
wireless communication means embedded in two or more of the plurality of processing dice and configured to carry wireless communication signals between one or more of the plurality of processing dice and the circuitry therein and wherein the machine learning operations comprise the communication signals.

20. The machine learning processor of claim 19 wherein the wireless communication means comprises one or more of electromagnetic coupling means and electromagnetic radiation means.
